(19) United States
(12) Patent Application Publication
(10) Pub. No.: US 2026/0066241 A1
(43) Pub. Date: Mar. 5, 2026

(54) INDUCTIVELY COUPLED PLASMA CHAMBER WITH ELECTRICALLY POWERED MAGNET RING

(71) Applicant: Applied Materials, Inc., Santa Clara, CA (US)

(72) Inventors: Kartik RAMASWAMY, San Jose, CA (US); Yang YANG, San Diego, CA (US); Michael D. WILLWERTH, Campbell, CA (US); Zhiming JIANG, Pleasonton, CA (US); Yuhui ZHANG, Santa Clara, CA (US); Xingxing WANG, Santa Clara, CA (US); Yogananda SARODE VISHWANATH, Bangalore (IN)

(21) Appl. No.: 18/823,295

(22) Filed: Sep. 3, 2024

(51) Int. Cl. H01J 37/32

(52) U.S. Cl. CPC H01J 37/32669; H01J 37/321; H01J 37/32651; H01J 2237/334

(57) ABSTRACT

The present disclosure provides a substrate processing chamber configured to produce an inductively coupled plasma. In one example, the substrate processing chamber has a chamber body and a substrate support assembly disposed within the chamber body. The substrate processing chamber has a lid assembly enclosing a processing region within the chamber body. The lid assembly has an inductive coil configured to generate a plasma within the processing region of the chamber body. A radio frequency shield encloses the inductive coil and at least one magnet is coupled to a magnet power source and disposed outside of the radio frequency shield.

### BACKGROUND

### Field

Embodiments of the present invention generally relate to systems and apparatuses of semiconductor manufacturing, and, more particularly, to systems and methods of generating a plasma for semiconductor substrate processing.

### Description of the Related Art

Inductively coupled plasma (ICP) process chambers are used in semiconductor manufacturing and generally form plasmas by inducing current in a process gas disposed within the process chamber via one or more inductive coils disposed outside of the process chamber. The inductive coils may be disposed externally and separated electrically from the chamber by, for example, a dielectric lid. When radio frequency (RF) current is fed to the inductive coils via an RF feed structure from an RF power supply, an inductively coupled plasma can be formed inside the chamber from an electric field generated by the inductive coils.

Under certain process conditions, ICP process chambers may produce non-uniformities in the electric field distribution of the plasma formed at the substrate level away from the coils. For example, due to etch rate non-uniformities caused by the non-uniform electric field distribution in the plasma, a substrate etched by such a plasma may result in a non-uniform etch pattern on the substrate, such as an M-shaped etch pattern, e.g., a center low and edge low etch surface with peaks between the center and edge.

Accordingly, there is a need for an improved plasma process apparatus to better control plasma processing non-uniformity.

### SUMMARY

The present disclosure provides a substrate processing chamber configured to produce an inductively coupled plasma. In one example, the substrate processing chamber has a chamber body and a substrate support assembly disposed within the chamber body. The substrate processing chamber has a lid assembly enclosing a processing region within the chamber body. The lid assembly has an inductive coil configured to generate a plasma within the processing region of the chamber body. A radio frequency shield encloses the inductive coil and at least one magnet is coupled to a magnet power source and disposed outside of the radio frequency shield.

In another example, the substrate processing chamber has a chamber body and a substrate support assembly disposed within the chamber body. The substrate processing chamber additionally has a lid assembly enclosing a processing region within the chamber body. The lid assembly has an inductive coil configured to generate a plasma within the processing region of the chamber body. A radio frequency shield encloses the inductive coil. A first magnet is disposed on a bottom portion of the radio frequency shield and a second magnet is disposed on a top portion of the radio frequency shield and additionally has a plurality of third magnets.

In another example, the substrate processing chamber has a chamber body and a substrate support assembly disposed within the chamber body having a chamber liner. A substrate support assembly is disposed within the chamber body having a cathode liner. A lid assembly encloses a processing region within the chamber body. The lid assembly has an inductive coil configured to generate a plasma within the processing region of the chamber body. A radio frequency shield encloses the inductive coil and an upper magnet is disposed on an upper portion of the chamber liner.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 illustrates a schematic, cross-sectional view of a substrate processing chamber, according to certain embodiments.

FIG. 2 illustrates a schematic, cross-sectional view of a portion of a substrate processing chamber, according to certain embodiments.

FIG. 3 illustrates a schematic, cross-sectional view of a portion of a substrate processing chamber, according to certain embodiments.

FIG. 4 illustrates a schematic, cross-sectional view of a portion of a substrate processing chamber, according to certain embodiments.

FIG. 5A illustrates a schematic, cross-sectional view of a substrate processing chamber, according to certain embodiments.

FIGS. 5B and 5C illustrate a schematic, cross-sectional view of a portion of the substrate processing chamber of FIG. 5A, according to certain embodiments.

FIGS. 5D and 5E illustrate a schematic, cross-sectional view of a portion of the substrate processing chamber of FIG. 5A, according to certain embodiments.

FIG. 6A illustrates a schematic, cross-sectional view of a portion of a substrate processing chamber, according to certain embodiments.

FIG. 6B illustrates a perspective view of an adapter of the substrate processing chamber of FIG. 6A, according to certain embodiments.

FIG. 6C illustrates a perspective view of a vacuum feedthrough of the substrate processing chamber of FIG. 6A, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to systems and apparatuses of semiconductor manufacturing, and, more particularly, to systems and methods of generating a plasma for semiconductor substrate processing.

An inductively coupled plasma (ICP) is generated in a substrate processing chamber by supplying energy through electric currents produced by electromagnetic induction, i.e., by time-varying magnetic fields. An induction coil forms a strong magnetic field inside the chamber. When a time-varying electric current is passed through the coil, a time-varying magnetic field is created. This magnetic field induces an azimuthal electromotive force in a process gas, leading to the formation of electron trajectories and thus generating plasma. The ICP torch consumes about 1250-1550 W of power, but this depends on the elemental composition of the sample due to different ionization energies. Improving the etch rate of generated plasma is often desirable. A faster etch rate can increase the efficiency of the etching process, reducing the time it takes to remove material from the surface of a wafer. This is particularly beneficial for applications with deep features. Improving the etch rate can also enhance the uniformity of the etching across the wafer.

Uniformity in plasma ionization is crucial for semiconductor manufacturing. However, achieving uniform plasma in ICP systems can be challenging. For example, design constraints may result in systems which have asymmetric gas pumping. This can in turn produce azimuthal non-uniformities in plasma properties. These asymmetries are reinforced by a positive feedback between non-uniformities in conductivity and power deposition. Additionally, the uniformity of the incoming ion flux within the plasma may degrade as the magnetic field of the induction coils decreases, e.g., due to distance away from the coils.

The present disclosure provides a substrate processing chamber configured to produce an inductively coupled plasma. The substrate processing chamber includes magnets disposed near induction coils, along the chamber body, and on a substrate support assembly. The strength of a magnetic field decreases as the distance from the source of the field increases⁷. This is due to the inverse square law, which states that the strength of the magnetic field is inversely proportional to the square of the distance from the source⁶. The magnetic field strength can be calculated using the following:

$$B = \frac{{μ}_{0} I}{2 π {r}^{2}}$$

where ‘B’ is the magnetic field strength, ‘I’ is the current, ‘r’ is the distance from the magnet, and ‘μ0’ is the permeability of free space.

As the distance from the magnet, increases, the magnetic field strength decreases. In an ICP chamber, additional magnetic fields can confine plasma, focusing the plasma onto the substrate surface rather than allowing the plasma to interact with the chamber walls. This is achieved by setting up magnetic field lines toroidally around the interior of the chamber. The ions and electrons in the plasma are forced to travel tightly around these field lines. Further, the additional magnetic fields energize electrons that participate in the ionization of gas molecules and atoms at low pressure.

The magnets produce a magnetic field that will confine and enhance plasma intensity by magnetize the plasma ions. This limits plasma interaction with the outer portions of the processing volume, e.g., the chamber walls, so as to allow high power application without increasing the risk of hardware damage. Magnetizing the plasma using the substrate processing chamber of the present disclosure also prolongs plasma decay by inhibiting electron diffusion, thus enhancing and expanding the process pulsing window, particularly regarding the zero-power 3rd state. The addition of the magnets also increases the plasma etch rate. The magnet disposed on the substrate support assembly allows for further tuning of the plasma uniformity on the substrate surface, which is particularly favorable for edge uniformity tuning.

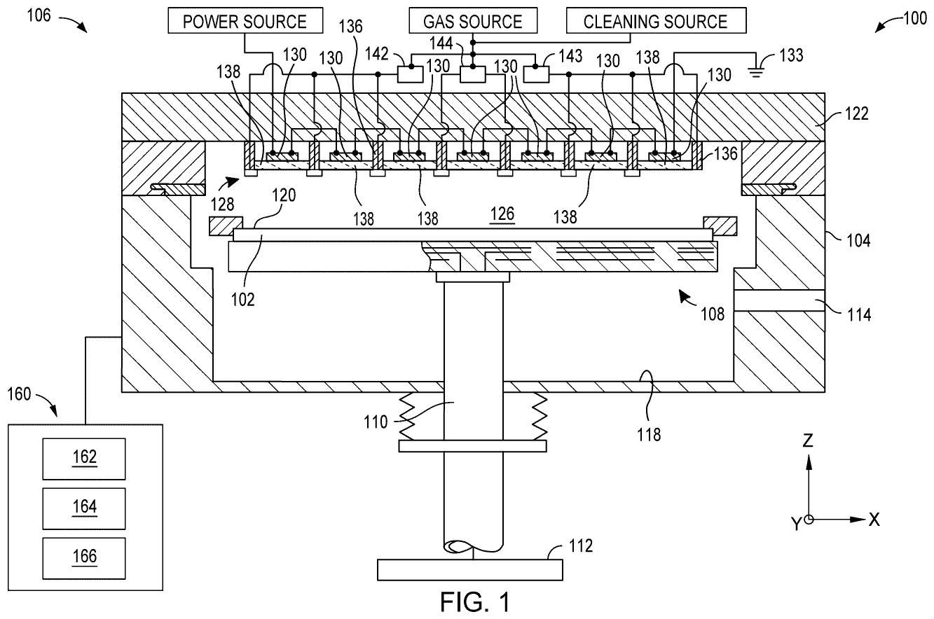

FIG. 1 illustrates a schematic, cross-sectional view of a substrate processing chamber 100, according to certain embodiments. A substrate 102 is shown having a substrate surface 120 within a chamber body 104. In one embodiment, the substrate 102 includes a dielectric material (e.g., SiO₂, SiOₓN_{y}), a semiconductive material (e.g., silicon or doped silicon), a barrier material (SiNₓ, SiOₓN_{y}), or a combination thereof. The substrate processing chamber 100 also includes a lid assembly 106, a bottom 118 disposed opposite the lid assembly 106, and a pedestal or substrate support assembly 108 disposed between the lid assembly 106 and the bottom 118. The lid assembly 106 is disposed at an upper end of the chamber body 104, and the substrate support assembly 108 is at least partially disposed within the chamber body 104. The substrate support assembly 108 is coupled to a shaft 110. The shaft 110 is coupled to a drive 112 that moves the substrate support assembly 108 vertically (in the Z direction) within the chamber body 104. The substrate support assembly 108 of the substrate processing chamber 100 shown in FIG. 1 is in a processing position. However, the substrate support assembly 108 may be lowered in the Z direction to a position adjacent to a transfer port 114.

The lid assembly 106 may include a backing plate 122 that rests on the chamber body 104. The lid assembly 106 also functions as a plasma source 128. To function as the plasma source 128, the lid assembly 106 includes one or more inductively coupled plasma generating components, or inductive coils 130. Each of the one or more inductive coils 130 may be a single inductive coil 130, two inductive coils 130, or more than two inductive coils 130, and are simply described as inductive coils 130 hereafter. Each of the one or more inductive coils 130 are coupled across a power source and ground 133. Although FIG. 1 depicts each of the inductive coils 130 connected to the power source and ground 133 in series, a connection in parallel is also contemplated such that each inductive coil 130 is connected and controlled independently to the power source and ground 133. In some embodiments, ground 133 is a capacitor. The power source includes a match circuit or a tuning capability for adjusting electrical characteristics of the inductive coils. For example, the power source may supply RF power at 13.56 MHz to the inductive coil 130 to generate an inductively coupled plasma within the chamber body 104 and the match circuit configured for a 13.56 MHz match.

Each dielectric window 138 is supported by a support member 136. Each of the one or more inductive coils 130 or portions of the one or more inductive coils 130 are positioned on or over a respective dielectric window 138. Each of the one or more inductive coils 130 is configured to create an electromagnetic field that energizes a process gas into a plasma in a processing region 126 as gas is flowing into the processing region 126. In some embodiments, process gases from the gas source are provided to the processing region 126 via conduits in the support members 136. The volume or flow rate of gases entering and leaving the processing region 126 are controlled in different zones of the processing region 126. Zone control of processing gases is provided by a plurality of flow controllers, such as mass flow controllers 142, 143 and 144. For example, the flow rate of gases to peripheral or outer zones of the processing region 126 is controlled by the flow controllers 142, 143, while the flow rate of gases to a central zone of the processing region 126 is controlled by the flow controller 144. When chamber cleaning is required, cleaning gases from a cleaning gas source is flowed to the processing region 126 within which the cleaning gases are energized into ions, radicals, or both. The energized cleaning gases flow into the processing region 126 in order to clean chamber components. In one embodiment, the process gases includes argon (Ar), nitrogen (N₂), nitrogen dioxide (NO₂), helium (He), oxygen (O₂), carbon dioxide (CO₂), hydrogen (H₂), ammonia (NH₃), phosphine, nitrogen trifluoride (NF₃), ammonia (NH₃), fluorine (F₂), sulfur hexafluoride (SF₆), silane (SiH₄), tetraethyl orthosilicate (TEOS), water vapor (H₂O), or a combination thereof.

The substrate processing chamber 100 further includes a controller 160 to control one or more components of the substrate processing chamber 100 to perform operations on the substrate 102. The controller 160 generally includes the central processing unit (CPU) 162, the memory 164, and the support circuits 166. The CPU 162 may be one of any form of a general purpose processor that can be used in an industrial setting. The memory 164, or non-transitory computer-readable medium, is accessible by the CPU 162 and may be one or more of memory such as random access memory (RAM), read only memory (ROM), floppy disk, hard disk, or any other form of digital storage, local or remote. The support circuits 166 are coupled to the CPU 162 and may comprise cache, clock circuits, input/output subsystems, power supplies, and the like. The various methods disclosed herein may generally be implemented under the control of the CPU 162 by the CPU 162 executing computer instruction code stored in the memory 164 (or in memory of a particular processing chamber) as, for example, a software routine. When the computer instruction code is executed by the CPU 162, the CPU 162 controls the processing chambers to perform processes in accordance with the various methods.

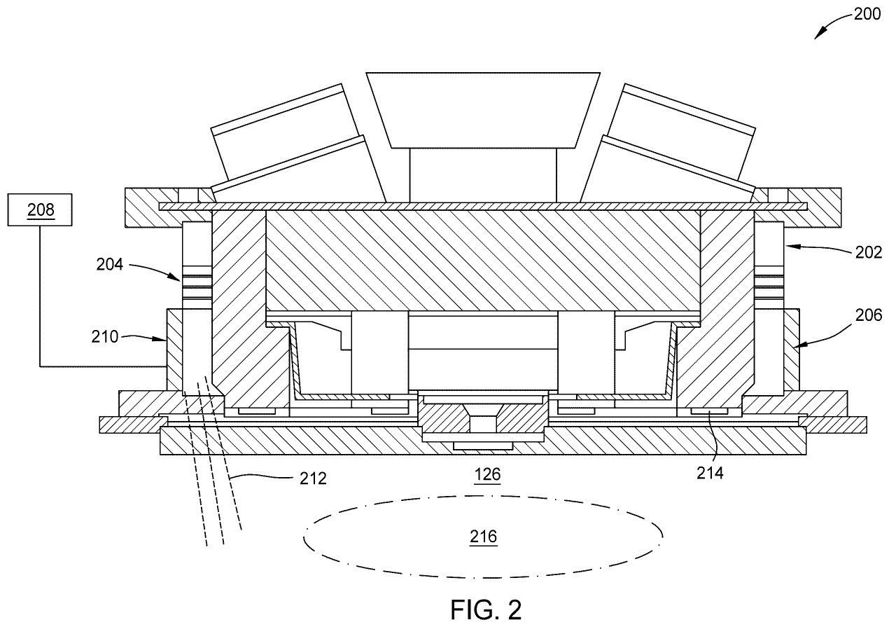

FIG. 2 illustrates a schematic, cross-sectional view of a portion 200 of a substrate processing chamber, according to certain embodiments. The portion 200, configured to be disposed above substrate processing chamber 100, e.g., above the lid assembly 106, includes a radio frequency (RF) shield 202 optionally having an RF mesh portion 204. At least one magnet 206 is disposed on an outer surface of the RF shield 202 and is coupled to a magnet power source 208. A magnet shield 210 may be disposed on the exposed surface of the at least one magnet 206 opposite the RF shield 202. The at least one magnet 206 is configured to generate a magnetic field 212 into the processing region 126. The portion 200 includes induction coils 214 configured to generate a plasma 216 using a processing gas flowed into the processing region 126. The magnetic field 212 generated by the at least one magnet 206 affects the plasma 216. For example, the magnetic field 212 may energize and increase the uniformity of ionization within the plasma 216 and, subsequently, increase the etch rate of the plasma 216.

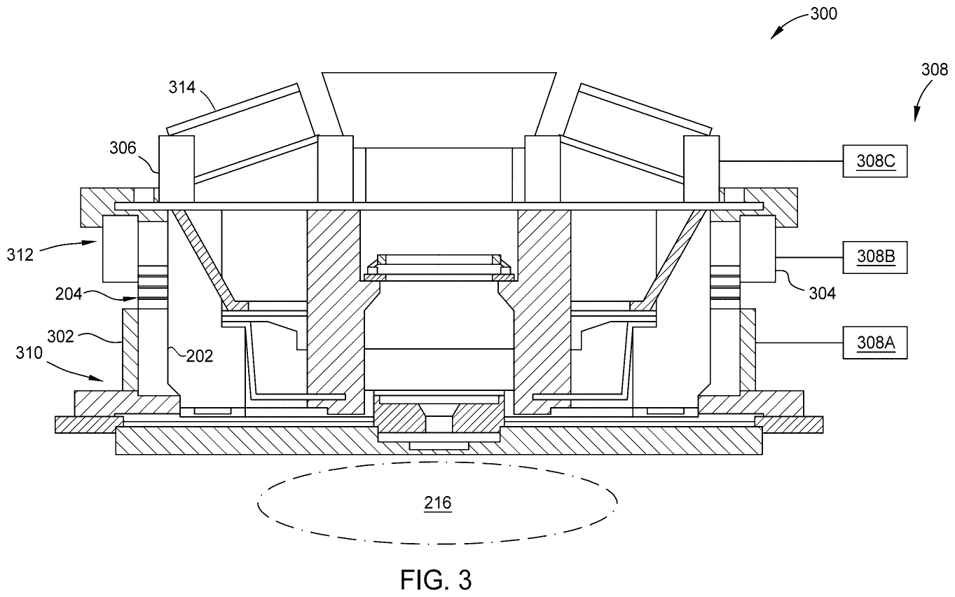

FIG. 3 illustrates a schematic, cross-sectional view of a portion 300 of a substrate processing chamber, according to certain embodiments. The portion 300 of the substrate processing chamber 100 is similarly configured to the portion 200 and differs as described. The portion 300 includes a first magnet 302, a second magnet 304, and a plurality of third magnets 306. The first magnet 302 is disposed on a bottom portion 310 of the RF shield 202, e.g., below the RF mesh portion 204. The second magnet 304 is disposed on a top portion 312 of the RF shield 202, e.g., above the RF mesh portion 204. The plurality of third magnets 306 are disposed surrounding each of a plurality of fans 314 disposed above the RF shield 202. The first magnet 302, the second magnet 304, and the plurality of third magnets 306 are configured to energize the plasma 216 generated by the inductive coils 214 by generating their own magnetic fields. The additional magnetic fields supply additional power to the ions in the plasma, improving plasma uniformity and increasing the plasma etch rate.

Each of the first magnet 302, the second magnet 304, and the plurality of third magnets 306 are coupled to a magnet power source 308, e.g., a first magnet power source 308A, a second magnet power source 308B, and a third magnet power source 308C. For example the magnet power source 308 may be coupled to each of the first magnet 302, the second magnet 304, and the plurality of third magnets 306 individually, e.g., powering each of the first magnet 302, the second magnet 304, and the plurality of third magnets 306 individually. Alternatively, the magnet power source 308 may be a single power source coupled to each of the first magnet 302, the second magnet 304, and the plurality of third magnets 306 such that the same power, e.g., the same voltage, is delivered to each simultaneously. The voltage supplied by the magnet power source 308 may range from about 0 V to about 40 V with the supplied current ranging from about 0 A to about 25 A. The power supplied, however, is dependent on the location of the magnets with respect to the processing region. For example, the first magnet 302 disposed on the bottom portion 310 of the RF shield 202 may require less power to generate the desired magnetic field than the plurality of third magnets 306 disposed on or around the plurality of fans 314 as the plurality of third magnets 306 are located further from the plasma 216.

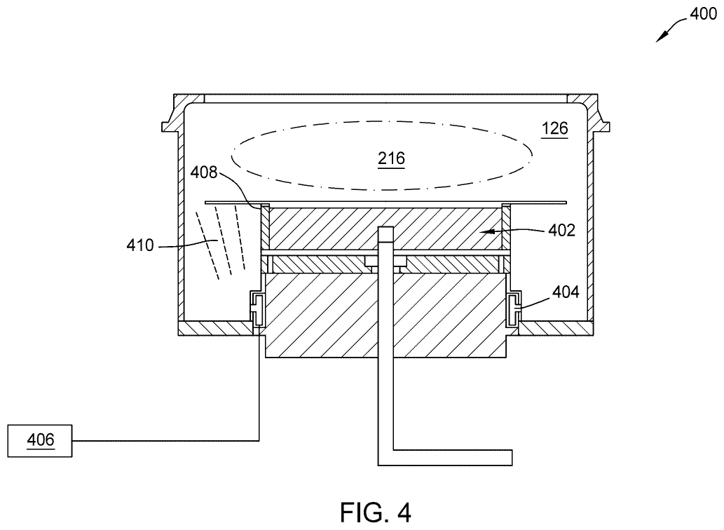

FIG. 4 illustrates a schematic, cross-sectional view of a portion 400 of a substrate processing chamber, according to certain embodiments. The portion 400 encompasses the processing region 126 having a substrate support assembly 402 disposed therein. The substrate support assembly 402 is configured similarly to the substrate support assembly 108 of FIG. 1 except as otherwise described. The substrate support assembly 402 includes a substrate support magnet 404 coupled to a substrate support magnet power source 406 and disposed under a substrate support liner 408 of the substrate support assembly 402. The substrate support magnet 404 is disposed below the substrate support surface of the substrate support assembly 402 and is configured to generate a magnetic field 410 that affects a plasma generated by an inductive coil, e.g., the plasma 216 generated by the induction coils 214. For example, the substrate support magnet 404 may generate a magnetic field 410 that will energize a plasma, e.g., the plasma 216, near the surface of the substrate, improving the uniformity and energy of the plasma 216 and increasing the etch rate. The magnetic field 410 from the substrate support magnet 404 is particularly useful in chambers without other magnetic field sources or chambers with large throw distances as the magnetic field produced by the induction coils 214 loses strength the further away the substrate support assembly 402 is located.

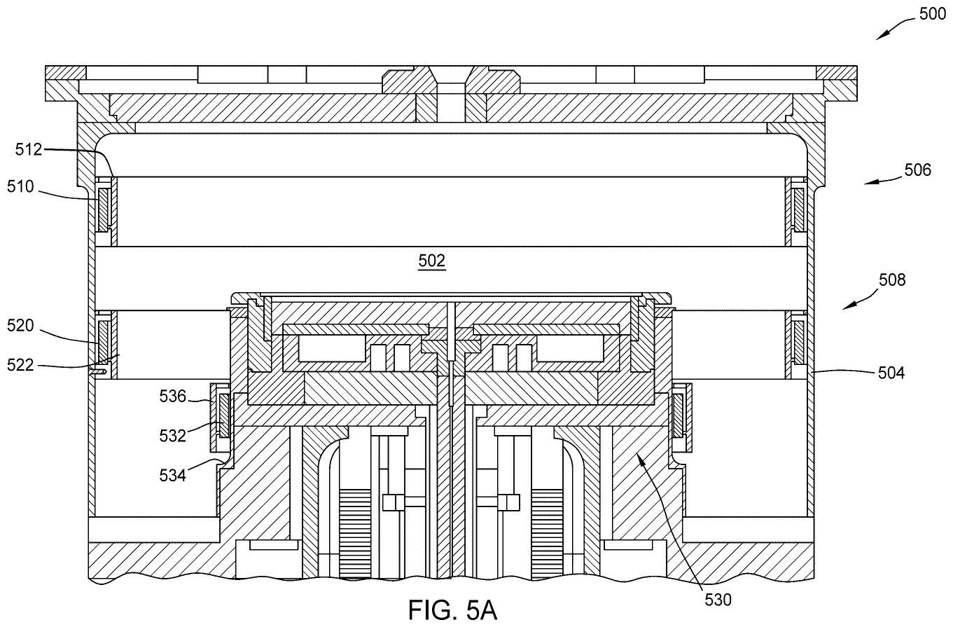

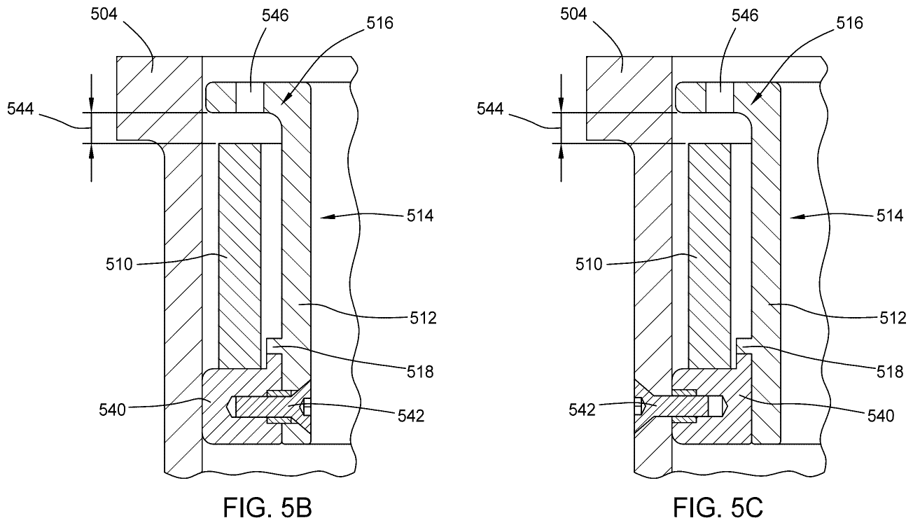

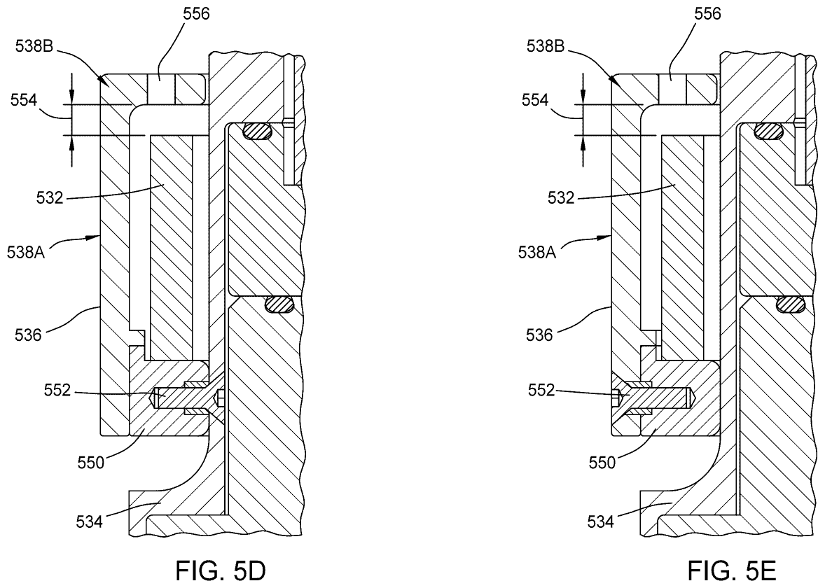

FIG. 5A illustrates a schematic, cross-sectional view of a portion 500 of a substrate processing chamber, according to certain embodiments. The portion 500 includes a processing region 502 configured similarly to the processing region 126 except as otherwise described. The processing region 502 is bound by a chamber liner 504 having an upper portion 506 and a lower portion 508. An upper magnet 510 having an upper magnet shield 512 is disposed on the upper portion 506 of the chamber liner 504 and within the processing region 502, e.g., not outside of the processing chamber. The upper magnet 510 is annular and is disposed along a perimeter of the chamber liner 504, e.g., is concentric with the chamber liner 504, and encircles the processing region 502. A lower magnet 520 having a lower magnet shield 522 is disposed on the lower portion 508 of the chamber liner 504 and within the processing region 502, e.g., not outside of the processing chamber. Similar to the upper magnet 510, the lower magnet 520 is annular and encircles the processing region 502 along the chamber liner 504.

The upper magnet shield 512 and the lower magnet shield 522 allow magnetic fields generated by the upper magnet 510 and the lower magnet 520 to permeate into the processing region 502 while covering the upper magnet 510 and the lower magnet 520, respectively, to protect the magnets from the plasma generated within the processing region 502. As such the upper magnet shield 512 and the lower magnet shield 522 are made of plasma-resistant materials. For example, the upper magnet shield 512 and the lower magnet shield 522 may be made of plasma resistant materials, such as silicon carbide, anodized aluminum, chrome, or a combination thereof. Each of the upper magnet 510 and the lower magnet 520 may include an electromagnetic coil, the electromagnetic coil having about 20 to about 200 turns, such as about 50 to about 150 turns. The upper magnet 510 and the lower magnet 520 generate a uniform magnetic field inside the processing region 502 during operation, enhancing the plasma generated by the induction coils, e.g., the induction coils 214.

A substrate support assembly 530, configured similarly to the substrate support assembly 108 except as otherwise described, includes a substrate support magnet 532 disposed on an outer surface of a cathode liner 534 and inside the processing region 502. A substrate support magnet shield 536 is disposed outside of the substrate support magnet 532, enclosing the substrate support magnet 532 between the substrate support magnet shield 536 and the cathode liner 534. As with the upper magnet shield 512 and the lower magnet shield 522, the substrate support magnet shield 536 allows magnetic fields to permeate into the processing region 502 and is configured to protect the substrate support magnet 532 from the plasma generated in the processing region 502. This allows the substrate support magnet 532 to generate a magnetic field that will influence, e.g., energize, the plasma in the processing region 502 effectively as the substrate support magnet 532 is located within the processing region 502 itself.

FIGS. 5B and 5C illustrate a schematic, cross-sectional view of a close-up portion of the substrate processing chamber of FIG. 5A, according to certain embodiments. Specifically, FIGS. 5B and 5C illustrate close-up views of how the magnets, e.g., the upper magnet 510 and the lower magnet 520, are disposed on and mounted to the chamber liner 504. FIG. 5B illustrates an embodiment of the upper magnet 510 or the lower magnet 520 mounted on the chamber liner 504. FIG. 5C illustrates an alternative embodiment of the upper magnet 510 or the lower magnet 520 mounted on the chamber liner 504. Although these embodiments are described separately, it is within the scope of this disclosure that the upper magnet 510 may be mounted as described in FIG. 5B, the lower magnet 520 may be mounted as described in FIG. 5C, or vice versa.

As shown in FIG. 5B, the upper magnet 510 is disposed on a mount 540 disposed on the chamber liner 504. The upper magnet shield 512 is secured to the mount 540 using a fastener 542. The upper magnet shield 512 is L-shaped such that there is a parallel portion 514 parallel to a length of the upper magnet 510 and a perpendicular portion 516 perpendicular to the length of the upper magnet 510. The upper magnet 510 is then enclosed by the upper magnet shield 512, the mount 540, and the chamber liner 504. The upper magnet shield 512 may include a protrusion 518 extending from the parallel portion 514 configured to rest on the mount 540. The protrusion 518 allows for sufficient support of the upper magnet shield 512 while allowing a gap 544 to exist between the upper magnet 510 and the upper magnet shield 512. The gap 544 extends along the upper magnet shield 512, including to the perpendicular portion 516. The upper magnet shield 512 also includes connection through holes 546, e.g., through the perpendicular portion 516, that allows for connections from a magnet power source, e.g., the magnet power source 308, to connect to the upper magnet 510. The connection through holes 546 may be sealed to protect the connection through holes 546 and the upper magnet 510 from the plasma generated within the processing region 502. Alternatively, as shown in FIG. 5C, the upper magnet shield 512 and the mount 540 are mounted to the chamber liner 504 using the fastener 542. Additionally, the mount 540 may be mounted to the chamber liner 504 using the fastener 542 in while the upper magnet shield 512 is mounted to the chamber liner 504 using the fastener 542, essentially combining the embodiments shown in FIGS. 5B and 5C.

FIGS. 5D and 5E illustrate a schematic, cross-sectional view of a portion of the substrate processing chamber of FIG. 5A, according to certain embodiments. Specifically, FIGS. 5D and 5E illustrate close-up views of how a magnet, e.g., the substrate support magnet 532, is disposed on and mounted to the cathode liner 534. FIG. 5D illustrates an embodiment of the substrate support magnet 532 mounted on the cathode liner 534. FIG. 5E illustrates an alternative embodiment of the substrate support magnet 532 mounted on the cathode liner 534.

As shown in FIG. 5D, the substrate support magnet 532 is disposed on a mount 550 disposed on the cathode liner 534. The substrate support magnet shield 536 is secured to the mount 550 using a fastener 552. The substrate support magnet shield 536 is L-shaped such that there is a parallel portion 538A parallel to a length of the substrate support magnet 532 and a perpendicular portion 538B perpendicular to the length of the substrate support magnet 532. The substrate support magnet 532 is then enclosed by the substrate support magnet shield 536, the mount 550, and the cathode liner 534. The substrate support magnet shield 536 may include a protrusion 518 extending from the parallel portion 538A configured to rest on the mount 550. The protrusion 518 allows for sufficient support of the substrate support magnet shield 536 while allowing a gap 554 to exist between the substrate support magnet 532 and the substrate support magnet shield 536. The gap 554 extends along the substrate support magnet shield 536, including to the perpendicular portion 538B. The substrate support magnet shield 536 also includes connection through holes 556, e.g., through the perpendicular portion 538B, that allows for connections from a magnet power source, e.g., the magnet power source 308, to connect to the substrate support magnet 532. The connection through holes 556 may be sealed to protect the connection through holes 556 and the substrate support magnet 532 from the plasma generated within the processing region 502. Alternatively, as shown in FIG. 5E, the substrate support magnet shield 536 and the mount 550 are mounted to the cathode liner 534 using the fastener 552. Additionally, the mount 550 may be mounted to the cathode liner 534 using the fastener 552 in while the substrate support magnet shield 536 is mounted to the cathode liner 534 using the fastener 552, essentially combining the embodiments shown in FIGS. 5D and 5E.

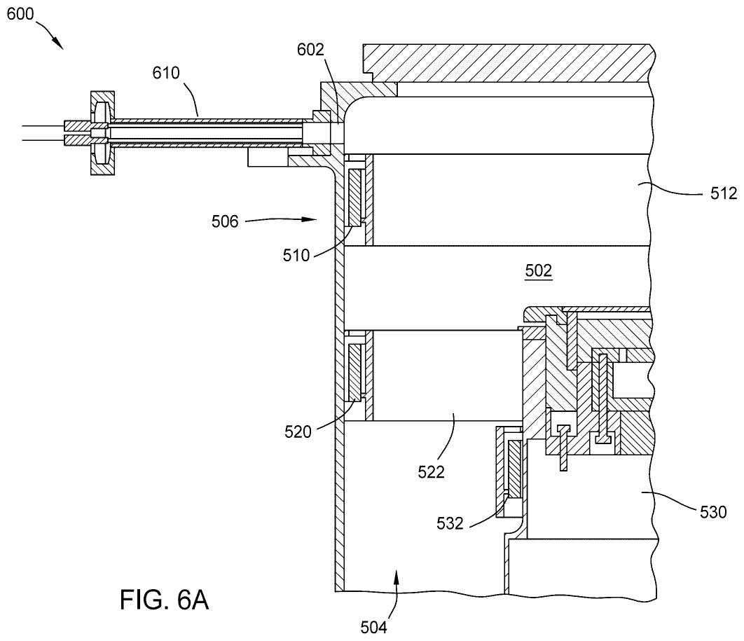

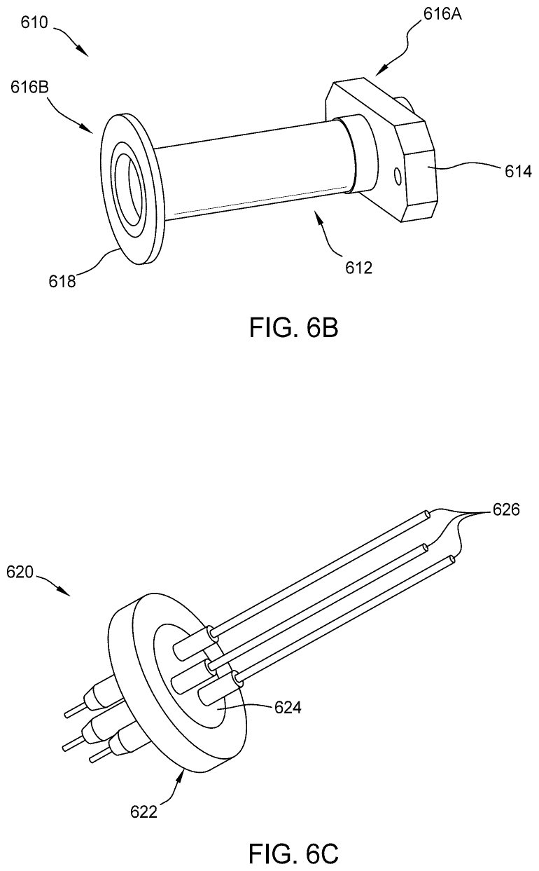

FIG. 6A illustrates a schematic, cross-sectional view of a portion 600 of a substrate processing chamber, according to certain embodiments. Specifically, FIG. 6A illustrates a portion 600 that facilitates operation of magnets within the processing volume, e.g., the upper magnet 510, the lower magnet 520, and the substrate support magnet 532 of FIGS. 5A-5E, during operation. FIG. 6B illustrates a perspective view of an adapter of the substrate processing chamber of FIG. 6A, according to certain embodiments. FIG. 6C illustrates a perspective view of a vacuum feedthrough of the substrate processing chamber of FIG. 6A, according to certain embodiments.

As shown in FIG. 6A, a chamber body, e.g., the chamber body 104 of FIG. 1, includes a port 602 in the upper portion 506 of the chamber. For example, the port 602 may be located above the upper magnet 510. Alternatively, the port 602 may be disposed through the chamber body 104 as desired, such as between the upper magnet 510 and the lower magnet 520 or below the lower magnet 520. The port 602 is configured to couple to an adapter 610. The adapter 610, as shown in FIG. 6B, includes an adapter housing 612 that encloses a vacuum feedthrough 620, as shown in FIG. 6C, having a seal body 622 and a plurality of holes 624. The adapter 610 and the port 602 allow for electrical connections 626, e.g., wires or conduits, to pass through the chamber body 104 and into the processing region 502 while maintaining the vacuum within the processing region 502. In particular, the adapter housing 612 may include an adapter coupling 614 on a first end 616A that couples the adapter housing 612 to the port 602, e.g., via fasteners (not shown), as well as a vacuum seal portion 618 on a second end 616B opposite the first end 616A that encloses the seal body 622. The seal body 622, along with the vacuum seal portion 618, preserves the vacuum pressure within the processing region 502 while allowing wires to enter from outside of the chamber body 104, e.g., through the plurality of holes 624 of the seal body 622. The plurality of holes 624 are configured to provide a vacuum seal around the electrical connections 626, e.g., the wires or conduits, which pass through into the processing region 502.

The present disclosure provides a substrate processing chamber configured to produce an inductively coupled plasma. The substrate processing chamber includes magnets disposed near induction coils, along the chamber body, and on a substrate support assembly. The magnets produce a magnetic field that confines and enhances plasma intensity. This limits plasma interaction with the outer portions of the processing volume, e.g., the chamber walls, so as to allow high power application without increasing the risk of hardware damage. Magnetizing the plasma using the substrate processing chamber of the present disclosure also prolongs plasma decay by inhibiting electron diffusion, thus enhancing and expanding the process pulsing window, particularly regarding the zero-power 3rd state. The addition of the magnets also increases the plasma etch rate. The magnet disposed on the substrate support assembly allows for further tuning of the plasma uniformity on the substrate surface, which is particularly favorable for edge uniformity tuning.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
a chamber body;
a substrate support assembly disposed within the chamber body;
a lid assembly enclosing a processing region within the chamber body, the lid assembly comprising an inductive coil configured to generate a plasma within the processing region of the chamber body;
a radio frequency shield enclosing the inductive coil; and
at least one magnet coupled to a magnet power source and disposed outside of the radio frequency shield.

2. The substrate processing chamber of claim 1, further comprising a magnet shield disposed over the at least one magnet and configured to contain a magnetic field generated by the at least one magnet.

3. The substrate processing chamber of claim 1, wherein the at least one magnet is configured to energize the plasma generated by the inductive coil.

4. The substrate processing chamber of claim 1, further comprising a substrate support magnet disposed on the substrate support assembly and configured to energize the plasma generated by the inductive coil.

5. A substrate processing chamber, comprising:
a chamber body;
a substrate support assembly disposed within the chamber body;
a lid assembly enclosing a processing region within the chamber body, the lid assembly comprising an inductive coil configured to generate a plasma within the processing region of the chamber body;
a radio frequency shield enclosing the inductive coil;
a first magnet disposed on a bottom portion of the radio frequency shield;
a second magnet disposed on a top portion of the radio frequency shield; and
a plurality of third magnets.

6. The substrate processing chamber of claim 5, wherein the plurality of third magnets are disposed around a plurality of fans disposed above the lid assembly.

7. The substrate processing chamber of claim 5, wherein the first magnet is coupled to a first magnet power source, the second magnet is coupled to a second magnet power source, and the plurality of third magnets are coupled to a third magnet power source.

8. The substrate processing chamber of claim 5, wherein the substrate support assembly comprises a substrate support magnet disposed under a substrate support liner of the substrate support assembly.

9. The substrate processing chamber of claim 8, wherein the substrate support magnet is coupled to a substrate support magnet power source.

10. The substrate processing chamber of claim 5, wherein the first magnet, the second magnet, and the plurality of third magnets are configured to energize the plasma generated by the inductive coil in the processing region.

11. The substrate processing chamber of claim 8, wherein the substrate support magnet is configured to energize the plasma generated by the inductive coil, wherein energizing the plasma includes generating a magnetic field.

12. A substrate processing chamber, comprising:
a chamber body comprising a chamber liner;
a substrate support assembly disposed within the chamber body comprising a cathode liner;
a lid assembly enclosing a processing region within the chamber body, the lid assembly comprising an inductive coil configured to generate a plasma within the processing region of the chamber body;
a radio frequency shield enclosing the inductive coil; and
an upper magnet disposed on an upper portion of the chamber liner.

13. The substrate processing chamber of claim 12, further comprising an upper magnet shield disposed over the upper magnet and configured to allow a magnetic field to permeate into the processing region of the chamber body.

14. The substrate processing chamber of claim 12, further comprising a lower magnet disposed on a lower portion of the chamber liner.

15. The substrate processing chamber of claim 14, further comprising a lower magnet shield disposed over the lower magnet and configured to allow a magnetic field to permeate into the processing region of the chamber body.

16. The substrate processing chamber of claim 12, further comprising a substrate support magnet disposed on an outer surface of the cathode liner of the substrate support assembly.

17. The substrate processing chamber of claim 16, further comprising a substrate support magnet shield disposed over the substrate support magnet and configured to allow a magnetic field to permeate into the processing region of the chamber body.

18. The substrate processing chamber of claim 12, wherein the upper magnet is configured to energize the plasma generated by the inductive coil in the processing region of the chamber body.

19. The substrate processing chamber of claim 13, wherein the upper magnet shield comprises connection through holes.

20. The substrate processing chamber of claim 12, further comprising a port coupled to an adapter, the adapter comprising a vacuum seal portion coupled to a vacuum feedthrough configured to allow electrical connections through the port while maintaining a vacuum pressure in the processing region of the chamber body.
